(19) United States
(12) Patent Application Publication
(10) Pub. No.: US 2018/0152792 A1
(43) Pub. Date: May 31, 2018

(54) MEMS DEVICE

(71) Applicant: Cirrus Logic International Semiconductor Ltd., Edinburgh (GB)

(72) Inventors: Tsjerk Hans HOEKSTRA, Balerno (GB); Axel THOMSEN, Austin, TX (US); Colin Robert JENKINS, Linlithgow (GB); Aleksey Sergeyevich KHENKIN, Nashua, NH (US)

(73) Assignee: Cirrus Logic International Semiconductor Ltd., Edinburgh (GB)

(21) Appl. No.: 15/826,255

(22) Filed: Nov. 29, 2017

Related U.S. Application Data
(63) Continuation-in-part of application No. 15/363,863, filed on Nov. 29, 2016, now Pat. No. 9,813,831.
Application No. 15/363,863 is a continuation-in-part of application No. 15/363,798, filed on Nov. 29, 2016, now Pat. No. 9,900,707.
(60) Provisional application No. 62/438,144, filed on Dec. 22, 2016.

(30) Foreign Application Priority Data
Jan. 17, 2017 (GB) 1700804.6

(51) Int. Cl. H04R 9/08; H04R 29/00; B81B 3/00

(52) U.S. Cl. CPC H04R 9/08; H04R 29/004; B81B 3/0086; B81B 2201/0257; B81B 2203/0127; B81B 2203/04; H04R 2201/003

(57) ABSTRACT

A MEMS transducer comprising: a flexible membrane, the flexible membrane comprising a first membrane electrode; a back plate, the back plate comprising a first back plate electrode; wherein the back plate is supported in a spaced relation with respect to the flexible membrane. The MEMS transducer is configured to provide electrical connections to the first membrane electrode and the first back plate electrode. The flexible membrane further comprises a second membrane electrode, the second membrane electrode being electrically isolated from the first membrane electrode, wherein the first membrane electrode and the second membrane electrode are arranged to reduce variation in electrostatic forces across the flexible membrane.

This application: (a) is a continuation-in-part of U.S. Non-Provisional application Ser. No. 15/363,863 filed on Nov. 29, 2016, issued as U.S. Pat. No. 9,813,831 on Nov. 7, 2017; (b) is a continuation-in-part of U.S. Non-Provisional application Ser. No. 15/363,798 filed on Nov. 29, 2016; (c) claims priority to United Kingdom Patent Application No. 1700804.6 filed Jan. 17, 2017; and (d) claims priority to U.S. Provisional Application Ser. No. 62/438,144, filed Dec. 22, 2016. All of the applications set forth in the previous sentence are incorporated by reference herein in their entirety.

A micro-electro-mechanical system (MEMS) transducer, in particular structures and circuitry relating to the use of a MEMS transducer as a capacitive transducer, for example in a capacitive microphone system.

Various MEMS devices are becoming increasingly popular. MEMS transducers, and especially MEMS capacitive microphones, are increasingly being used in portable electronic devices such as mobile telephones and portable computing devices.

Microphone devices formed using MEMS fabrication processes typically comprise one or more membranes with electrodes for read-out/drive deposited on the membranes and/or a substrate. In the case of MEMS pressure sensors and microphones, the read out is usually accomplished by measuring the capacitance between a pair of electrodes which will vary as the distance between the electrodes changes in response to sound waves incident on the membrane surface.

FIGS. 1A and 1B show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1A the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110.

The first cavity 109 may be formed using a first sacrificial layer during the fabrication process, i.e. using a material to define the first cavity which can subsequently be removed, and depositing the membrane layer 101 over the first sacrificial material. Formation of the first cavity 109 using a sacrificial layer means that the etching of the substrate cavity 108 does not play any part in defining the diameter of the membrane. Instead, the diameter of the membrane is defined by the diameter of the first cavity 109 (which in turn is defined by the diameter of the first sacrificial layer) in combination with the diameter of the second cavity 110 (which in turn may be defined by the diameter of a second sacrificial layer). The diameter of the first cavity 109 formed using the first sacrificial layer can be controlled more accurately than the diameter of a back-etch process performed using a wet-etch or a dry-etch. Etching the substrate cavity 108 will therefore define an opening in the surface of the substrate underlying the membrane 101.

A plurality of holes, hereinafter referred to as bleed holes 111, connect the first cavity 109 and the second cavity 110.

As discussed above the membrane may be formed by depositing at least one membrane layer 101 over a first sacrificial material. In this way the material of the membrane layer(s) may extend into the supporting structure, i.e. the side walls, supporting the membrane. The membrane and back-plate layer may be formed from substantially the same material as one another, for instance both the membrane and back-plate may be formed by depositing silicon nitride layers. The membrane layer may be dimensioned to have the required flexibility whereas the back-plate may be deposited to be a thicker and therefore more rigid structure. Additionally various other material layers could be used in forming the back-plate 104 to control the properties thereof. The use of a silicon nitride material system is advantageous in many ways, although other materials may be used, for instance MEMS transducers using polysilicon membranes are known.

In some applications, the microphone may be arranged in use such that incident sound is received via the back-plate. In such instances a further plurality of holes, hereinafter referred to as acoustic holes 112, are arranged in the back-plate 104 so as to allow free movement of air molecules, such that the sound waves can enter the second cavity 110. The first and second cavities 109 and 110 in association with the substrate cavity 108 allow the membrane 101 to move in response to the sound waves entering via the acoustic holes 112 in the back-plate 104. In such instances the substrate cavity 108 is conventionally termed a “back volume”, and it may be substantially sealed.

In other applications, the microphone may be arranged so that sound may be received via the substrate cavity 108 in use. In such applications the back-plate 104 is typically still provided with a plurality of holes to allow air to freely move between the second cavity and a further volume above the back-plate.

It should also be noted that whilst FIG. 1A shows the back-plate 104 being supported on the opposite side of the membrane to the substrate 105, arrangements are known where the back-plate 104 is formed closest to the substrate with the membrane layer 101 supported above it.

In use, in response to a sound wave corresponding to a pressure wave (for example, a sound wave) being incident upon the microphone, the membrane is deformed slightly from its equilibrium or quiescent position. The distance between the membrane electrode 102 and the back plate electrode 103 is correspondingly altered, giving rise to a change in capacitance between the two electrodes that is subsequently detected by electronic circuitry (not shown). The bleed holes allow the pressure in the first and second cavities to equalise over a relatively long timescale (in acoustic frequency terms) which reduces the effect of low frequency pressure variations, e.g. arising from temperature variations and the like, but without impacting on sensitivity at the desired acoustic frequencies.

The flexible membrane layer of a MEMS transducer generally comprises a thin layer of a dielectric material—such as a layer of crystalline or polycrystalline material. The membrane layer may, in practice, be formed by several layers of material which are deposited in successive steps. The flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located at least in the centre of the membrane 101, i.e. that part of the membrane which displaces the most. It will be appreciated by those skilled in the art that the membrane electrode may be formed by an alloy such as aluminium-silicon for example. Thus, known transducer membrane structures are composed of two layers of different material—typically a dielectric layer (e.g. SiN) and a conductive layer (e.g. AlSi).

A related application by the same applicant, U.S. Ser. No. 15/363,798, discloses a MEMS microphone comprising: comprising: a back plate comprising a first plurality of electrodes comprising at least a first electrode and a second electrode electrically isolated from one another and each is mechanically coupled to the back plate in a fixed relationship relative to the back plate; and a diaphragm configured to mechanically displace relative to the back plate as a function of sound pressure incident upon the diaphragm, wherein the diaphragm comprises a second plurality of electrodes, the second plurality of electrodes comprising at least a third electrode and a fourth electrode, wherein the third electrode and the fourth electrode are electrically isolated from one another and each is mechanically coupled to the diaphragm in a fixed relationship relative to the diaphragm such that the second plurality of electrodes mechanically displace relative to the back plate as the function of sound pressure incident upon the diaphragm; wherein: the first electrode and the third electrode form a first capacitor having a first capacitance which is a function of a displacement of the diaphragm relative to the back plate; the second electrode and the fourth electrode form a second capacitor having a second capacitance which is a function of the displacement of the diaphragm relative to the back plate; and each of the first capacitor and the second capacitor are biased by an alternating-current voltage waveform.

A further related application by the same applicant, U.S. Ser. No. 15/363,863, discloses a MEMS microphone, comprising: a back plate comprising a first plurality of electrodes comprising at least a first electrode and a second electrode electrically isolated from one another and each is mechanically coupled to the back plate in a fixed relationship relative 5 to the back plate; and a diaphragm configured to mechanically displace relative to the back plate as a function of sound pressure incident upon the diaphragm, wherein the diaphragm comprises a second plurality of electrodes, the second plurality of electrodes comprising at least a third electrode and a fourth electrode, wherein the third electrode and the fourth electrode are electrically isolated from one another and each is mechanically coupled to the diaphragm in a fixed relationship relative to the diaphragm such that the second plurality of electrodes mechanically displaces relative to the back plate as the function of sound pressure incident upon the diaphragm; wherein: the first electrode and the third electrode form a first capacitor having a first capacitance; the second electrode and the fourth electrode form a second capacitor having a second capacitance; and the first capacitor is configured to sense a mechanical displacement of the diaphragm responsive to which the second capacitor is configured to apply an electrostatic force to the diaphragm to return the diaphragm to an original position.

For some applications of membrane electrode structures, it can be useful if the flexible membrane comprises two electrodes, where the electrodes of the membrane are electrically isolated from one another. An example of an application wherein two electrodes on a flexible membrane can be useful is when extending the dynamic range of a capacitive microphone system, such that the microphone can be used to record a greater range of sound volumes.

A schematic of an example of a flexible membrane 201 comprising two electrodes is shown in FIG. 2. This configuration could be used, for example, in a capacitive microphone system having separate high and low gain monitoring channels, wherein a high gain electrode 203 is used in the high gain capacitive monitoring portion, and the low gain electrode 205 is used in the low gain capacitive monitoring portion. In the example shown in FIG. 2, the high gain electrode 203 has a larger surface area than the low gain electrode 205. This is because the high gain electrode 203 is intended to be used to monitor smaller amplitude incident pressure waves (sound waves), and therefore requires a greater degree of sensitivity than the low gain electrode 205.

If a flexible membrane is configured to comprise two independent electrodes, these two electrodes can be used to form a pair of capacitors to be used in a pair of capacitive monitoring systems. Depending on the configuration of the other elements of the system (and the surrounding electronics) one of the capacitive systems can output a higher gain signal than the other capacitive system. In this way, one of the two independent electrodes on the membrane can be used to monitor quieter sounds (as part of the higher gain capacitive system), and the other electrode can be used to monitor louder sounds (as part of the lower gain capacitive system). Therefore, the flexible membrane can be used to provide a capacitive microphone capable of monitoring a larger dynamic range than would be possible using a flexible membrane comprising a single electrode.

In a system as shown in FIG. 2, each electrode may therefore be coupled to an amplifier of different gain. However in addition to the acoustic pressure and the elastic restoring force of the membrane, there are also electrostatic forces on the electrodes. These are dependent on the electric field across the gap between membrane and back-plate electrodes and also on the charge on the membrane electrode. Thus if different electronic circuitry is attached to each of the two membrane electrodes, this is likely to result in the electrostatic forces exerted on each of the electrodes being different. For an arrangement of electrodes as shown in FIG. 2, the result of the variation in the electrostatic forces on the electrodes may be that the flexible membrane 201 moves differently at or near the first electrode than at or near the second electrode, causing a rocking or tilting or bending of the flexible membrane, rather than a relatively uniform displacement. This can lead to a resonant mode being excited in the flexible membrane 201 during operation that may not have been excited in a structure with a single electrode.

As discussed above, known membrane structures are configured to deform from an equilibrium position in response to an incident pressure wave (such as a sound wave), and then the elastic nature of the membrane applies a restorative force pushing the membrane back toward the equilibrium position. The exact nature of the deformation is determined both by the form of the membrane, and by the properties of the incident pressure wave. Certain incident pressure waves may interact with the flexible membrane in such a way as to cause the flexible membrane to resonate. Resonance is most likely to occur when the frequency of the incident pressure wave or other stimulus matches a resonant frequency of the flexible membrane.

Occurrences of resonance in the flexible membrane negatively impact on the functionality of MEMS transducers (such as capacitive microphones). Also, if the flexible membrane resonance causes large amplitude oscillations of the flexible membrane, lasting damage to a flexible membrane is possible, particularly in the event that the resonant oscillation causes the membrane to deform beyond design tolerances or to collide with a back-plate or substrate edge or other structure in the device.

In systems in which a plurality of electrodes are included on the flexible membrane, the behaviour of the system upon the incidence of a pressure wave can be more unpredictable. As discussed above, variation in electrostatic forces between the electrodes can increase the susceptibility of a flexible membrane configuration to resonance. Other factors can also increase the susceptibility of the membrane to resonance, including the mass distribution across the flexible membrane and the relative stiffness of different regions of the membrane.

The inclusion of one or more further electrodes (in addition to the first electrode) on the membrane can result in an uneven mass distribution across the membrane. As a result of an uneven mass distribution, it can be more difficult to predict the oscillatory behaviour of a membrane across a range of potential incident pressure wave frequencies and amplitudes. In particular, an uneven mass distribution may result in an unpredictable resonant frequency of the membrane that is located within a desired sensing frequency range.

As a result of the positioning of the electrodes in the example shown in FIG. 2, the distribution of mass across the flexible membrane 201 is not balanced. Accordingly, this flexible membrane 201 may be susceptible to unpredictable resonant behaviour. As a result of this unpredictability, the use of the membrane 201 as a capacitive sensor may be more difficult and less efficient and the membrane 201 may also be more susceptible to damage (as discussed in greater detail above).

The positioning of the electrodes on the flexible membrane 201 shown in FIG. 2 may also result in the relative stiffness of the membrane varying significantly across the membrane surface. This is because areas of the membrane comprising an electrode are typically less elastic than regions not comprising an electrode. Again, an uneven stiffness distribution across the membrane can result in unpredictable membrane response, and may lead to unwanted resonance effects. It is desirable to provide a flexible membrane comprising plural electrodes that are electrically isolated from one another, wherein the electrodes are configured to avoid excitation of resonant modes of the flexible membrane, and wherein the electrodes are further configured to move uniformly across the membrane and in unison with one another.

An example of the invention provides a MEMS transducer comprising: a flexible membrane, the flexible membrane comprising a first membrane electrode; a back plate, the back plate comprising a first back plate electrode; wherein the back plate is supported in a spaced relation with respect to the flexible membrane; and wherein the MEMS transducer is configured to provide electrical connections to the first membrane electrode and the first back plate electrode; the flexible membrane further comprising a second membrane electrode, the second membrane electrode being electrically isolated from the first membrane electrode, wherein the first membrane electrode and the second membrane electrode are arranged to reduce variation in electrostatic forces across the flexible membrane. By arranging the electrodes to reduce variation in electrostatic forces, it is possible to create a flexible membrane having first and second membrane electrodes that responds in a more predictable way to incident triggers, such as pressure waves.

In an example, the first membrane electrode and second membrane electrode are arranged to provide a flexible membrane electrode layout having an order of rotational symmetry. The symmetry of the electrode layout helps to prevent resonance and unpredictable membrane behaviour

In an example, the back plate is configured such that a surface of the back plate comprising the first back plate electrode and facing the flexible membrane is substantially parallel to a surface of flexible membrane comprising the first membrane electrode and facing the back plate; and the shape of the first back plate electrode at least partially mirrors the shape of the first membrane electrode. Use of a first back plate electrode that at least partially mirrors the shape of the first membrane electrode increases the number of configuration options for the MEMS transducer, allowing the MEMS transducer to be used in a broader range of applications.

### DESCRIPTION OF FIGURES

The present invention is described, by way of example only, with reference to the Figures, in which:

FIG. 1A is a schematic diagram of a known capacitive MEMS microphone device.

FIG. 1B is a perspective view of the known capacitive MEMS microphone device of FIG. 1A.

FIG. 2 is schematic diagram of a known flexible membrane comprising two electrodes.

FIG. 3A is a schematic diagram showing a plan view of a flexible membrane of an example.

FIG. 3B is a schematic diagram showing a side view of the example shown in FIG. 3A.

FIG. 4 is a schematic diagram showing a plan view of a flexible membrane of an example.

FIG. 5 is a schematic diagram showing a plan view of a flexible membrane of an example.

FIG. 6A shows a detailed diagram of an electrode layout in accordance with an example.

FIG. 6B shows a detailed diagram of an electrode layout in accordance with an example.

FIG. 7 is a schematic diagram showing a plan view of a flexible membrane of an example.

FIG. 8A shows a detailed diagram of an electrode layout in accordance with an example.

FIG. 8B shows a detailed diagram of an electrode layout in accordance with an example.

FIG. 9 is a schematic diagram showing a plan view of a flexible membrane of an example.

FIG. 10A is a schematic showing locations in which a back plate electrode may be located, superimposed over the view of a flexible membrane as shown in FIG. 5.

FIG. 10B is a schematic diagram showing a side view of an example including a first back plate electrode and a second back plate electrode.

FIG. 11A is a circuit diagram showing an example of a circuit suitable for use in a capacitive microphone.

FIG. 11B is a circuit diagram showing an example of a circuit suitable for use in a capacitive microphone.

FIG. 11C is a circuit diagram showing an example of a circuit suitable for use in a capacitive microphone.

FIG. 11D is a circuit diagram showing an example of a circuit suitable for use in a capacitive microphone.

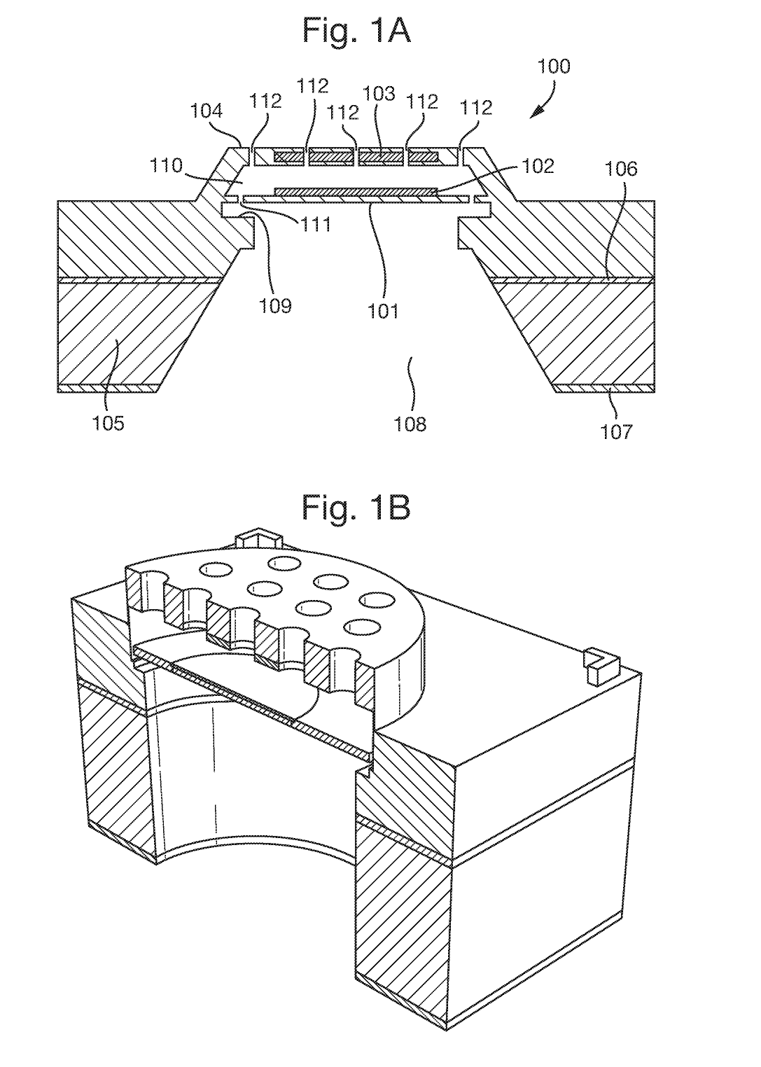

### DETAILED DESCRIPTION

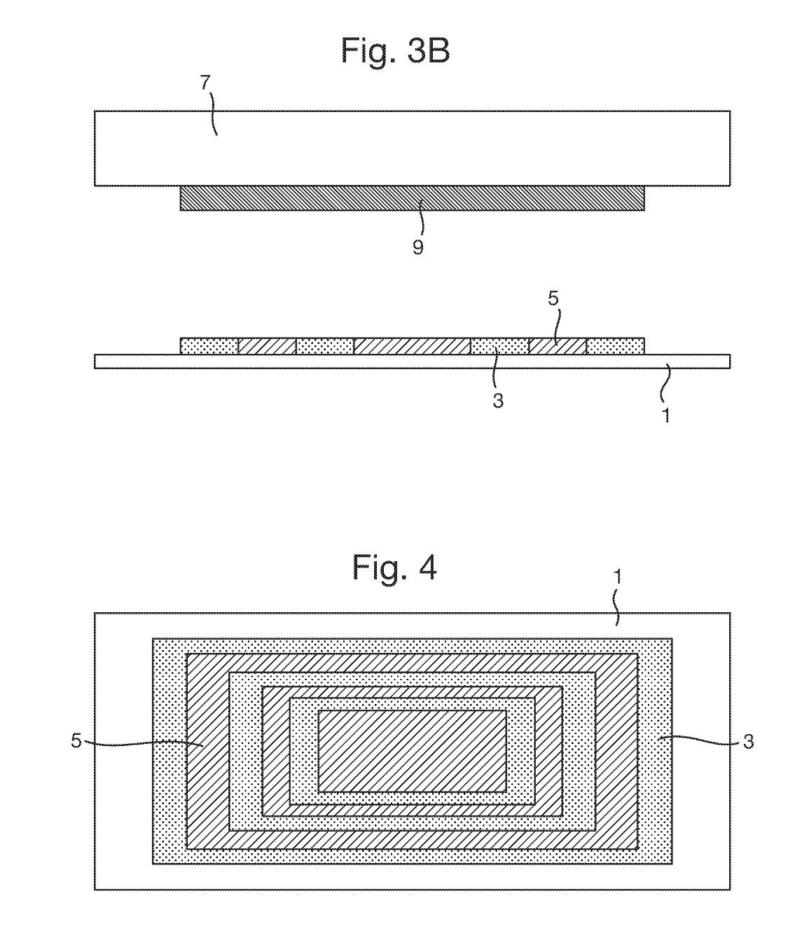

The example shown schematically in FIG. 3A comprises a flexible membrane 1, wherein the flexible membrane comprises a first membrane electrode 3 and a second membrane electrode 5. FIG. 3A shows a plan view of the membrane 1 viewed from the location of a back plate 7 (not shown in FIG. 3A); this position allows the arrangement of the first membrane electrode 3 and a second membrane electrode 5 to be clearly seen. FIG. 3B shows a side view schematic of the same example, in which the back plate 7 and first back plate electrode 9 are also shown. In FIG. 3B, the location of the first membrane electrode 3 and second membrane electrode 5 on the surface of the flexible membrane 1 can be seen. FIG. 3B also shows the back plate 7, including the first back plate electrode 9. In the example shown in FIG. 3, the back plate 7 comprises a single back plate electrode (the first back plate electrode 9); in other examples additional back plate electrodes may be present, as discussed in greater detail below.

The back plate 7 is held in a spaced relation with respect to the flexible membrane (as shown in FIG. 3B) by the surrounding architecture of the MEMS transducer. Typically, the MEMS transducer is formed from a substrate (such as a silicon wafer), and this substrate is formed in such a way as to support the back plate 7 and the flexible membrane 1 in a spaced relationship, while still allowing the flexible membrane 1 to move from an equilibrium position in response to incident pressure waves. As discussed above, the spacing between the flexible membrane 1 and the back plate 7 varies as the flexible membrane is displaced from an equilibrium position by incident pressure waves.

The MEMS transducer includes separate electrical connections to the first membrane electrode 3, second membrane electrode 5, and first back plate electrode 9. A first capacitor is formed between the first membrane electrode 3 and the first back plate electrode 9, and a second capacitor is formed between the second membrane electrode 5 and the first back plate electrode 9. By monitoring variations in the capacitances recorded by the first capacitor and the second capacitor, it is possible to monitor the movement of the flexible membrane 1 relative to the back plate 7. The MEMS transducer can thus be used in capacitive sensors, such as capacitive microphones.

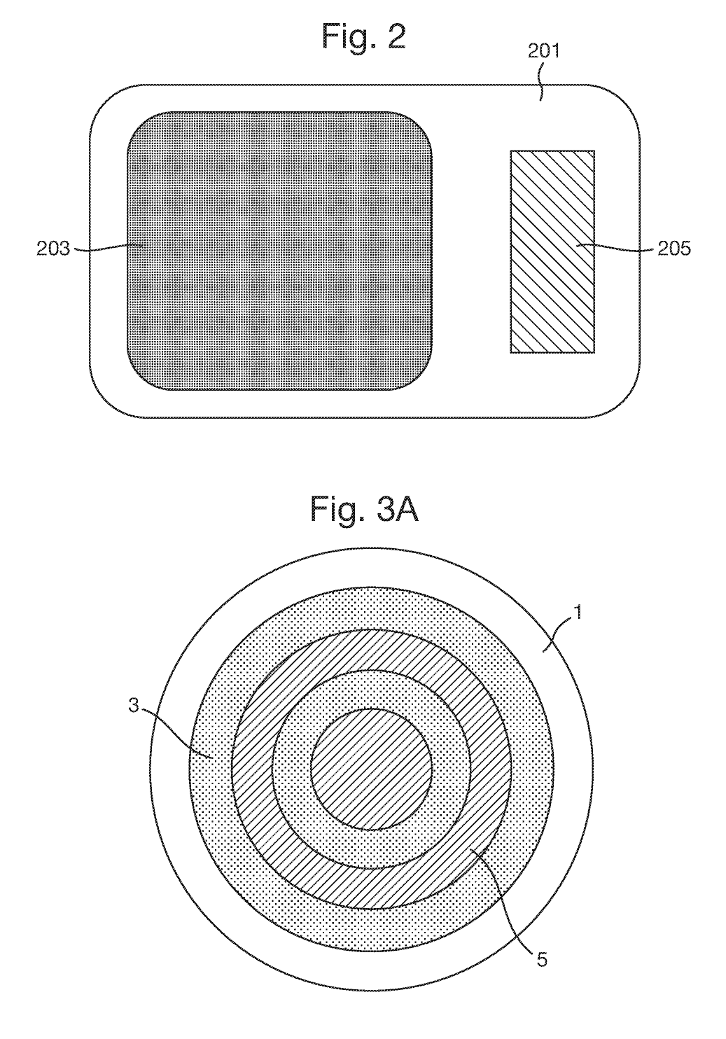

In order to allow undesired resonant modes of the flexible membrane to be suppressed, such that the response of the MEMS transducer to incident pressure waves is more efficient and predictable, the flexible membrane, first membrane electrode 3 and second membrane electrode 5 are arranged to avoid exciting unwanted resonant modes of the flexible membrane 1. In some examples (such as the example shown in FIGS. 3A and 3B), the flexible membrane 1, first membrane electrode 3 and second membrane electrode 5 are arranged to provide at least one order of rotational symmetry. Arranging the first membrane electrode 3 and second membrane electrode 5 symmetrically in this way provides a balanced flexible membrane 1, which is less susceptible to unwanted resonance than unbalanced membranes such as the membrane 201 shown in FIG. 2.

Each of the first membrane electrode 3 and second membrane electrode 5 may be divided into a plurality of discrete regions. This is the case with the example shown in FIGS. 3A and 3B, wherein the first membrane electrode 3 and second membrane electrode 5 are each divided into a plurality of annular regions. In alternative examples, the first membrane electrode 3 and second membrane electrode 5 may each be formed as a single continuous region.

In the example shown in FIGS. 3A and 3B, the plurality of annuli formed by the regions of the first membrane electrode 3 and the second membrane electrode 5 are arranged coaxially in a plane, the plurality of annuli having different inner and outer radii from one another and being arranged such that the first membrane electrode and second membrane electrode alternate with increasing radial separation from a centre of the annuli (which is located, in this example, at the centre of the circular membrane). When viewed from above, the arrangement of the first membrane electrode 3 and second membrane electrode 5 in the present example therefore resembles a target.

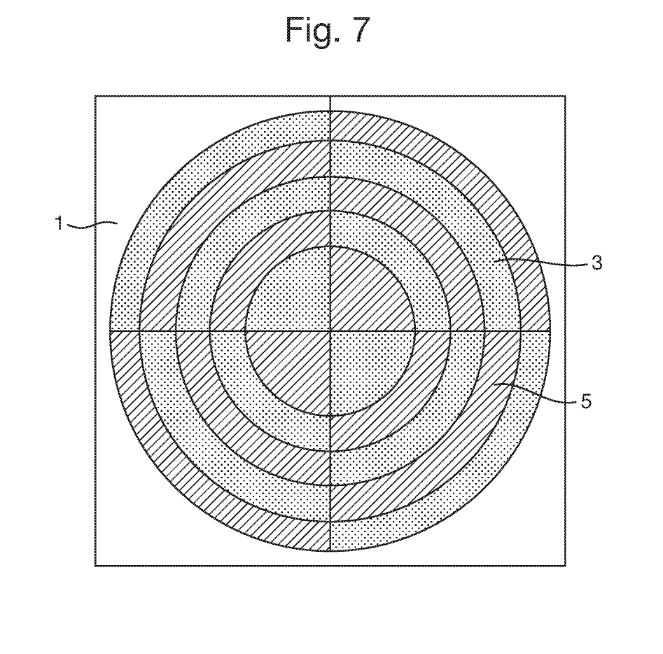

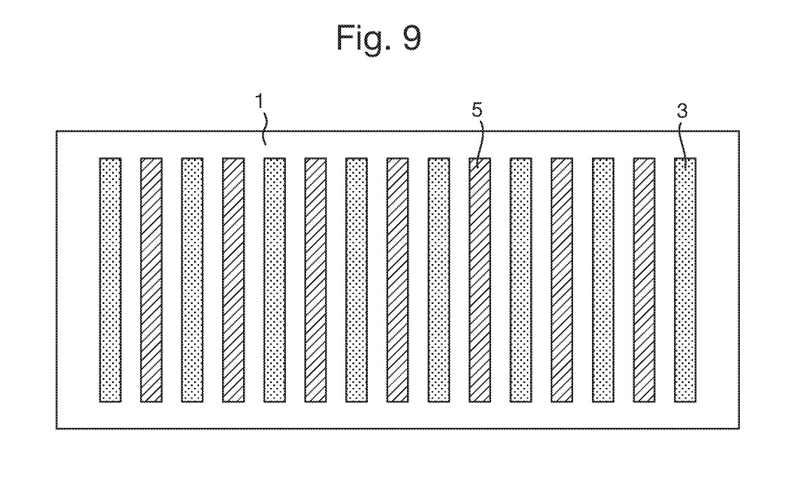

The electrodes on both the flexible membrane and the back plate require electrical connections in order to function. Where the first membrane electrode 3 and second membrane electrode 5 are not formed each as a single region, it is necessary for the separate regions of each electrode to be electrically connected together. The connections between the regions within an electrode may be formed within the same plane as the electrodes, or alternatively may be formed in a different plane to the electrodes (for example, deeper within the flexible membrane). The schematic diagram shown in FIGS. 3A and 3B does not show the connections between the separate regions of each of the first membrane electrode 3 and second membrane electrode 5. This is because the connections between the separate regions of each electrode do not significantly influence the resonance modes of the flexible membrane; the area occupied by the connections is negligible in comparison to the area occupied by the regions of the electrodes themselves. Also, for any given arrangement of regions of the first membrane electrode 3 and second membrane electrode 5, there are numerous ways in which the separate regions may be connected together, both in the plane of the electrodes and out of the plane of the electrodes. Accordingly, the connections between the separate regions of the electrodes are not taken into consideration when analysing the symmetry of the flexible membranes. FIGS. 6A, 6B, 8A and 8B show detailed diagrams of examples of electrode layouts including connections between different regions of; these detailed diagrams are discussed in greater detail below.

The example shown in FIG. 3A has a flexible membrane 1 that is substantially circular in shape. Accordingly, the flexible membrane 1 itself (not taking into consideration the arrangement of the first membrane electrode 3 and second membrane electrode 5, or details of electrical connections to the electrodes) has an infinite order of rotational symmetry. More symmetrical membranes are less susceptible to resonance effects, however for some uses of the MEMS transducer it may not be practical to utilise circular membranes. The use of circular shaped flexible membranes generally does not provide the best ratio of flexible membrane area that can be used to detect incident pressure waves relative to total area of the chip comprising the MEMS transducer.

The shape of the chip comprising the MEMS transducer (which, in turn, comprises the flexible membrane) is a key consideration when determining the shape of flexible membrane to use. Chips are typically formed in batches on large wafers, where the wafers are divided into plural chips after the chips have been formed. Often a single wafer may be divided into tens of thousands of chips. Chips are generally rectangular (or square) as this allows the division of the wafer into individual chips to be simply performed by dividing the wafer along lines at 90° angles to one another. This is simpler than dividing a wafer to extract a plurality of, for example, circular chips. Rectangular flexible membranes (and square flexible membranes, which are rectangular flexible membranes having equal side lengths throughout) make better use of the area of a rectangular chip. Accordingly, for uses of the MEMS transducer wherein the total area of the flexible membrane available to detect incident waves is key, rectangular shaped flexible membranes (including square flexible membranes) may be used.

Rectangular flexible membranes have two orders of rotational symmetry (not taking into consideration the arrangement of the first membrane electrode 3 and second membrane electrode 5, or details of electrical connections to the electrodes), except for in the special case of a square membrane wherein the order of rotational symmetry is 4. The arrangement of the first membrane electrode 3 and second membrane electrode 5 with respect to the membrane is typically intended to preserve as many of the innate orders of rotational symmetry allowed by the flexible membrane shape as possible.

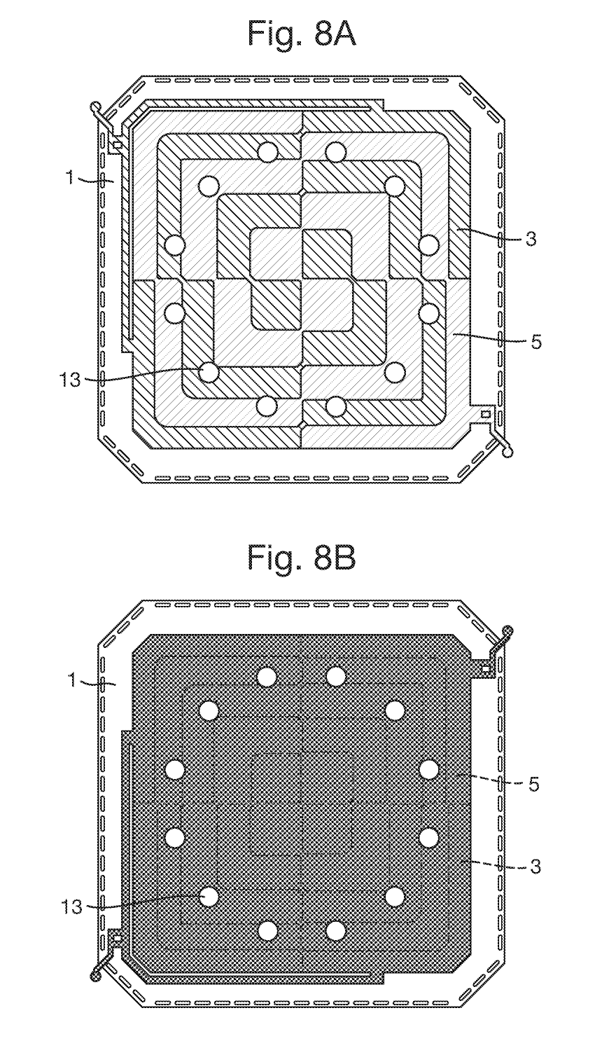

In the example shown in FIG. 3A, the first membrane electrode 3 and second membrane electrode 5 are each divided into plural annular regions, as discussed above. In the present example, the outline shape of the annular regions is the same as that of the flexible membrane; circular. However, it is not necessary for the outline shape of the electrodes to be the same as the shape of the flexible membrane, and some examples utilise different shapes (as shown in FIG. 7, for example).

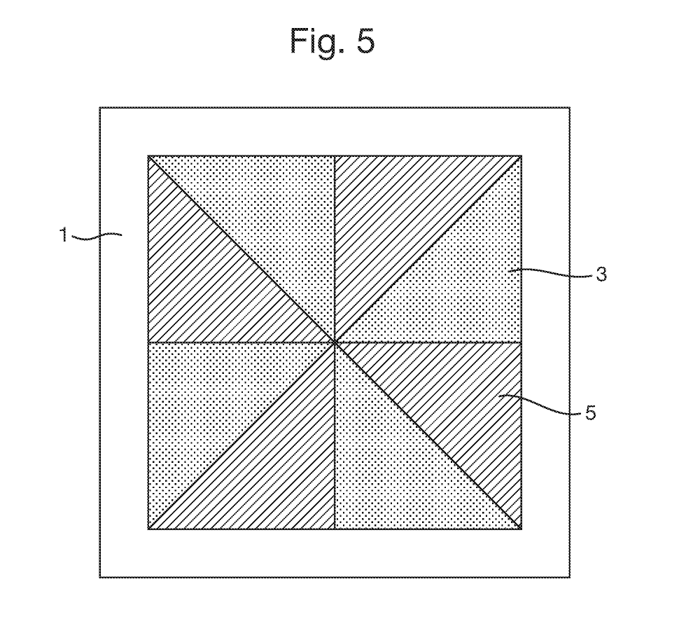

The arrangement used in the example shown in FIG. 3A maintains the order of rotational symmetry allowed by the flexible membrane, as discussed above. Arranging the first membrane electrode 3 and second membrane electrode 5 in annular portions is a reliable way of maintaining the order of rotational symmetry allowed by the flexible membrane shape, particularly where the annuli are of the same outline shape as the flexible membrane. The use of the term “annuli” should not be understood to require that the electrode regions have a circular profile; other shapes such as concentric rectangular annuli can also be used. FIG. 4 shows an example which includes concentric rectangular annuli. In particular, square outline electrode shapes can be used to maximise the available area of the electrodes.

In the example shown in FIG. 3A, each of the first membrane electrode 3 and second membrane electrode 5 comprises two separate regions. The alternative configuration shown in FIG. 4 includes three separate regions for each of the first membrane electrode 3 and second membrane electrode 5. The MEMS transducer is not limited to the use of two or three separate regions for each electrode; the number can be increased or decreased depending upon the particular requirements of the system.

Increasing the number of regions for each electrode for a given flexible membrane shape results in a reduction in the total space between regions of a given electrode (that is, the first membrane electrode 3 and second membrane electrode 5). Accordingly, the precision with which the movements of the membrane may be tracked using one of the electrodes is increased by increasing the number of regions of each electrode in the configuration. However, for some arrangements of the connections between the regions of an electrode in examples that use annular regions (particularly the arrangements that use connections in the plane of the electrodes), increasing the number of regions results in a reduction in the total area of the flexible membrane that is available to be occupied by one of the first membrane electrode 3 and second membrane electrode 5. This is because, in examples that use annular regions, it is necessary to leave gaps in the annuli for connections between electrode regions to pass through. The greater the number of electrode regions, the greater the number of connections between electrode regions and accordingly the greater the requirement for gaps in the annuli. The minimum size of the connections is determined by the membrane formation technology; the connections must be robust enough to withstand the movement of the flexible membrane, and narrower connections can be less robust especially when subject to continuous movement. Therefore, the number of regions used when the first membrane electrode 3 and second membrane electrode 5 are divided into annular portions is determined by balancing the need for precise measurement of each area of the flexible membrane against the need for total electrode area and ease of production.

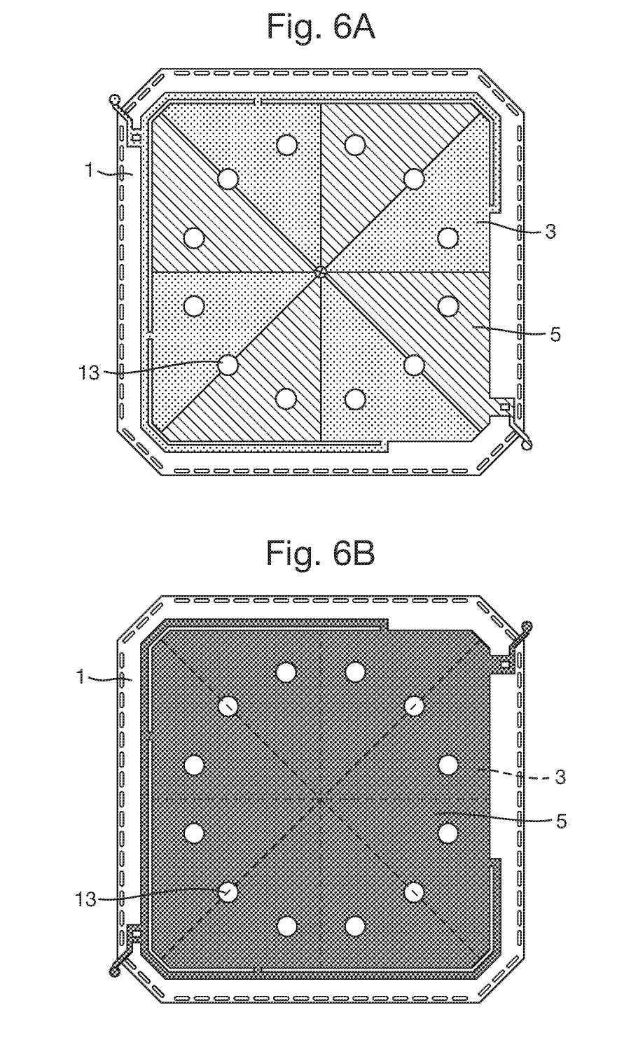

FIG. 5 shows a schematic of a further example. In the example shown in FIG. 5, the first membrane electrode 3 and second membrane electrode 5 are not divided into annular regions. Instead, the first membrane electrode 3 and second membrane electrode 5 are divided into sectors that are interspersed by gaps extending radially from the centre of the flexible membrane. The arrangement of the first membrane electrode 3 and second membrane electrode 5 into sectors (as in the example shown in FIG. 5) does not result in an arrangement having an infinite order of rotational symmetry, as is the case with the arrangement shown in FIG. 3A.

Instead, the order of rotational symmetry is determined by a combination of the shape formed by the first membrane electrode 3 and second membrane electrode 5 (a square in the example shown in FIG. 5), and also by the number of sectors into which the first membrane electrode 3 and second membrane electrode 5 are divided. In the example shown in FIG. 5, the arrangement results in four orders of rotational symmetry, because the flexible membrane and the electrodes both form square shapes and each of the first membrane electrode 3 and second membrane electrode 5 are divided into four separate sectors. In the example shown in FIG. 5 the sectors are of equal shape and area to preserve the rotational symmetry of the arrangement, although this is not essential and sectors of different areas and/or shapes could also be used.

If the flexible membrane 1 in the example shown in FIG. 5 were circular or octagonal, and each of the first membrane electrode 3 and second membrane electrode 5 were divided into eight sectors, an arrangement having 8 orders of rotational symmetry could be formed. By contrast, if the flexible membrane shape or the shape formed by the electrodes was a non-square rectangle, the order of rotational symmetry would be limited to two.

An advantage of the example arrangement shown in FIG. 5 is that each one of the separate regions forming the first membrane electrode 3 and second membrane electrode 5 extends to both the centre of the flexible membrane 1 and to the edge of the region occupied by the electrodes on the membrane 1. As a result of this feature, the connections between the regions can be formed more easily, potentially by providing connections that extend off the flexible membrane 1 region and join in a region of the MEMS transducer separate from the flexible membrane 1. In particular, it is not necessary to provide gaps in the regions for the purpose of allowing connections between the separate regions of an electrode, even in the case wherein all of the connections are formed in the plane of the electrodes (contrary to the arrangement shown in FIG. 3A, as discussed above). However, a limitation on the order of rotational symmetry is imposed by the electrode arrangement of FIG. 5.

FIGS. 6A and 6B show detailed diagrams of electrode arrangements for the first membrane electrode 3 and second membrane electrode 5; both of the arrangements are in accordance with the schematic shown in FIG. 5. FIG. 6A distinguishes between the first membrane electrode 3 and second membrane electrode 5, while FIG. 6B concentrates on the form of the electrode material. In FIG. 6A, the electrodes are formed from continuous layers of electrode material (typically a thin layer of metal or a metal alloy as discussed above). The configuration shown in FIG. 6A results in a robust electrode providing a high level of membrane coverage. However, a continuous electrode layer as shown in FIG. 6A can result in the flexible membrane 1 becoming more rigid, and losing a degree of sensitivity of response to pressure waves. Accordingly, and as shown in FIG. 6B, the electrodes may alternatively be formed from a lattice of interconnected tracks. Use of this lattice structure can produce electrodes which have a smaller effect on the rigidity of the flexible membrane, but which also provide a lower degree of coverage over the surface of the flexible membrane 1. A decision on whether or not a lattice structure is appropriate for the electrodes can be made depending on the intended use of the MEMS transducer comprising the flexible membrane 1.

The detailed diagrams in FIGS. 6A and 6B both include a series of circular holes 13 that are formed through the electrodes. These holes 13 are intended to accommodate optional vent holes which may be included in the flexible membranes 1 to provide a release mechanism in the event that the membrane is subjected to an unusually powerful pressure wave, thereby helping to prevent damage to the membrane. In the examples shown in FIGS. 6A and 6B, the circular holes 13 do not alter the order of rotational symmetry of the arrangement; in any event these holes 13 can be discounted when considering the order of rotational symmetry of an arrangement. This is because, as discussed above in the context of the connections between the regions of the electrodes, the overall impact of the circular holes 13 on the symmetry of the arrangement is small.

FIGS. 6A and 6B also show the connections between the regions of the first membrane electrode 3 and second membrane electrode 5. In the examples shown in FIGS. 6A and 6B, all of the connections between the regions are in the plane of the electrodes. The regions forming the first membrane electrode 3 are connected at the centre of the membrane, and the regions forming the second membrane electrode 5 are connected by a track circling a portion of the perimeter of the area of the flexible membrane occupied by the electrodes. The connection scheme shown in FIGS. 6A and 6B is an example of a connection scheme that can be used when the electrodes are divided into sectors; other connection schemes can also be used as discussed above.

A further example is shown schematically in FIG. 7. In this example, the arrangements of the first membrane electrode 3 and second membrane electrode 5 used in the examples shown in FIGS. 3A and 5 are combined. Each of the first membrane electrode 3 and second membrane electrode 5 are divided into annular regions, and the annular regions in turn are divided into sectors. The electrodes are arranged such that portions of the first membrane electrode 3 and second membrane electrode 5 alternate both with increasing radial separation from the centre of the annuli and also by sector within each annular region. That is, if a radial path is followed from the centre of the area of the flexible membrane where the electrodes are located (also the centre of the annuli in the example shown in FIG. 7), the path will pass through alternating regions of the first and second membrane electrode as it passes from annular region to annular region. Also, if a path is followed around the membrane at a constant separation from the centre of the area of the flexible membrane where the electrodes are located (such that the path remains within one of the annular regions shown in FIG. 7), the path will pass through alternating regions of the first and second membrane electrode as it passes from sector to sector. Accordingly, the first membrane electrode and second membrane electrode both trace a substantially spiral path.

Detailed diagrams of examples having electrodes arranged in substantially spiral paths are shown in FIGS. 8A and 8B. Analogously with the diagrams shown in FIGS. 6A and 6B, FIG. 8A shows an example wherein the electrodes are formed from continuous layers, and FIG. 8B shows an example wherein the electrodes have a lattice structure. FIG. 8A distinguishes between the first membrane electrode 3 and second membrane electrode 5, while FIG. 8B concentrates on the form of the electrode material. Both of FIGS. 8A and 8B also shown the circular holes 13 intended to accommodate optional vent holes which may be included in the membranes. FIGS. 8A and 8B show a substantially square example; the example shown schematically in FIG. 7 is circular.

The arrangements shown in FIGS. 7, 8A and 8B result in high coverage of the flexible membrane by the electrodes, particularly because it is not necessary to leave gaps between the electrode regions to facilitate the passage of connections between regions of an electrode. As shown in FIGS. 8A and 8B, the majority of the connections between electrode regions are formed directly between adjacent electrode regions, thus forming the “spiral” configuration of the electrodes. The order of rotational symmetry of the arrangements show in FIGS. 7, 8A and 8B is not as high as that of the arrangements shown in FIGS. 3A and 5.

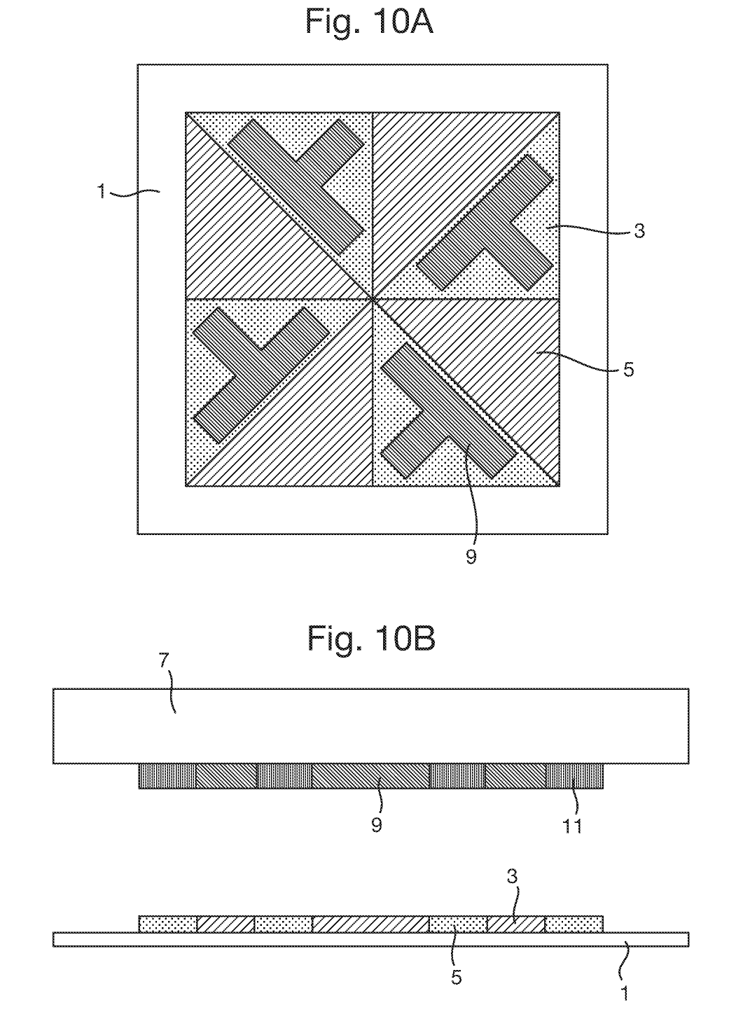

A further example configuration is shown in FIG. 9. In the example shown in FIG. 9, the first membrane electrode 3 and second membrane electrode 5 each comprise a plurality of regions, and the regions are substantially rectangular in shape. The regions are arranged so as to alternate along the length of the membrane, such that the regions are interleaved. The example shown in FIG. 9 uses a rectangular shape flexible membrane 1; this shape is particularly well suited to this arrangement of membrane electrode regions. Although other shapes (such as rectangular or hexagonal) of flexible membrane 1 can also be used with this arrangement of membrane electrode regions, it can be more difficult to balance the areas of the first and second membrane electrodes when non-rectangular flexible membranes 1 are used, as the relative sizes of the membrane regions are required to vary significantly across the flexible membrane 1 in order that the membrane electrodes occupy a large proportion of the available flexible membrane surface. If the relative sizes of the membrane regions are not varied significantly for a non-rectangular flexible membrane 1 (for example, if the membrane region arrangement shown in FIG. 9 is used with a circular flexible membrane 1), then a large amount of the available flexible membrane surface is not used.

Various arrangements of connections (not shown in FIG. 9) can be used to link together the discrete rectangular regions forming a membrane electrode, as discussed above. The connections may be formed in the same plane as the discrete regions, or out of this plane. However, typically the discrete regions forming one of the membrane electrodes are connected together using a single connector that runs perpendicular to the direction in which the discrete regions extend for the greatest distance. That is, the connector runs in the direction along which the discrete regions alternate. In this specific arrangement of connections, each of the first membrane electrode 3 and second membrane electrode 5 has a comb-like shape (when the connection is taken into consideration), and the two membrane electrodes together form an interdigitated arrangement. The separation between the discrete regions can be varied as required.

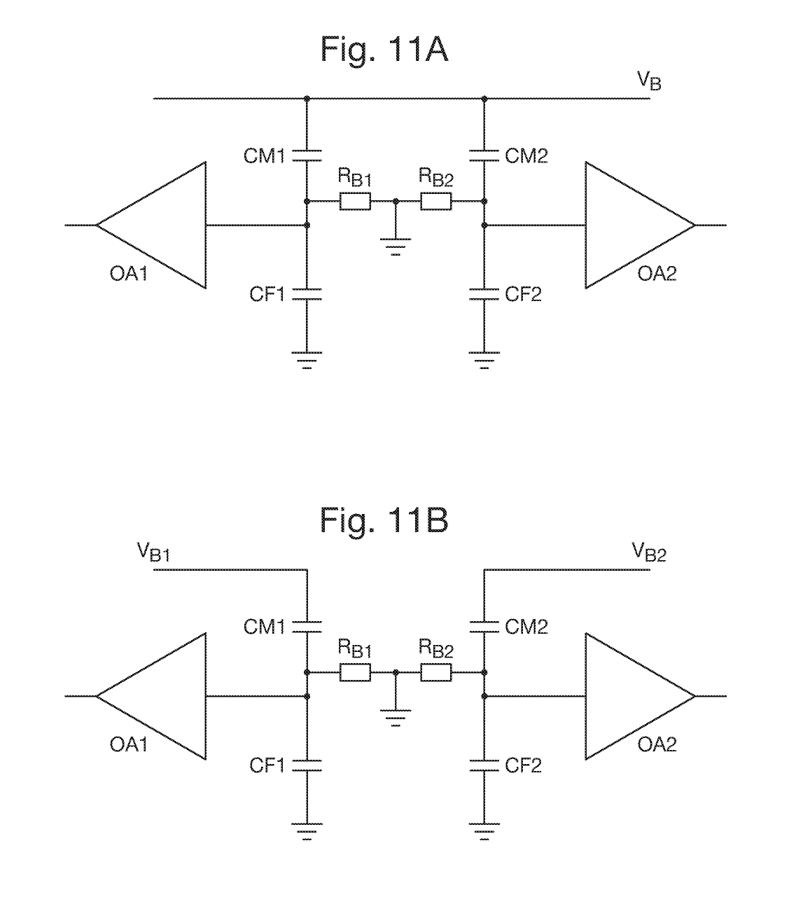

In all of the example discussed above, the first back plate electrode 9 may consist of a single continuous electrode formed on the surface of the back plate 7, as shown in FIG. 3B. However, all of the examples discussed above may alternatively include a back plate 7 and first back plate electrode 9 configured to further enhance the MEMS transducer. This is discussed in greater detail below, with reference to FIGS. 10A and 10B.

FIG. 10A is a schematic showing locations in which the first back plate electrode 9 may be located, superimposed over a view of a flexible membrane 1. The back plate 7 has been omitted from FIG. 10A, so that the locations of the back plate electrode 9 can be seen. The back plate 7 and first back plate electrode 9 may be configured such that the surface of the back plate 7 comprising the back plate electrode 9 is substantially parallel to the surface of the flexible membrane 1 comprising the first membrane electrode 3 and second membrane electrode 5. When viewed from a side on perspective (as shown in FIG. 10B, using a different example), the back plate 7 can be seen to be separate from and parallel to the flexible membrane 1.

The first back plate electrode 9 may be configured, instead of using a simple continuous layer structure formed on or within the back plate 7, to comprise a plurality of separate electrode regions that substantially mirror the arrangement of one or both of the first membrane electrode 3 and second membrane electrode 5. In FIG. 10A, the back plate 7 comprises a single electrode (the first back plate electrode 9) that is divided into four discrete regions, wherein the discrete back plate electrode regions are arranged in such a way as to partially mirror the shape of the first membrane electrode 3. The back plate electrode regions only partially mirror the shape of the first membrane electrode, in that the back plate electrode regions are located only in areas of the back plate 7 directly perpendicular to the regions of the flexible membrane 1 where the first membrane electrode 3 is located, but the back plate electrode regions are not located directly perpendicular to all of the regions of the flexible membrane 1 where the first membrane electrode 3 is located. In alternative examples, the back plate electrode 9 mirrors substantially all of the shape of the first membrane electrode 3, in that the back plate electrode regions are located in all of the areas of the back plate 7 directly perpendicular to the regions of the flexible membrane 1 where the first membrane electrode 3 is located (but are not located elsewhere in the back plate 7).

The configuration shown in FIG. 10A may be particularly useful, for example, in the event that the first membrane electrode 3 and first back plate electrode 9 form a capacitor for monitoring small deviations in the flexible membrane 1 position from equilibrium (caused by low magnitude incident pressure waves, for example), and the second membrane electrode 5 and the first back plate electrode 9 form a further capacitor for monitoring larger deviations in the flexible membrane 1 position from equilibrium (caused by high magnitude incident pressure waves, for example). The alignment between the first membrane electrode 3 and first back plate electrode 9 increases the sensitivity of this capacitive monitoring configuration, and the corresponding misalignment between the second membrane electrode 5 and first back plate electrode 9 reduces the sensitivity of this capacitive monitoring configuration. The arrangement is therefore particularly suitable for the separate monitoring of low and high magnitude pressure waves (for example, sound waves), as discussed above.

In the arrangement shown in FIG. 10A, the first back plate electrode 9 only partially mirrors the configuration of the first membrane electrode 3. If it is desired to further increase the sensitivity of the capacitive monitoring system formed by the first membrane electrode 3 and first back plate electrode 9, the first back plate electrode 9 can alternatively be configured to mirror substantially all of the first membrane electrode 3.

In the example shown in FIG. 10B, the first membrane electrode 3 and second membrane electrode 5 are both located on a surface of the flexible membrane that is parallel to (in an equilibrium position of the flexible membrane 1) and facing towards the back plate 7. Further the first back plate electrode 9 is located on a surface of the back plate 7 facing towards the flexible membrane 1. In order to enhance the sensitivity of capacitive monitoring that can be performed using the system, the back plate 7 includes a second back plate electrode 11, which is configured to mirror the shape of the second membrane electrode 5. In the example shown in FIG. 10B, the first back plate electrode 9 and second back plate electrode 11 mirror substantially all of the first membrane electrode 3 and second membrane electrode 5 respectively, however either or both of the back plate electrodes may alternatively be configured to mirror only a part of a membrane electrode (as shown in FIG. 10A and discussed above).

The partially or full mirroring of the membrane electrodes by back plate electrodes can be applied to any of the examples discussed above, in order to increase the sensitivity of the resulting MEMS transducer.

In further examples, there may be only a single membrane electrode but multiple back plate electrodes. The back plate electrodes may be arranged, for example, in similar patterns to the membrane patterns illustrated above in FIGS. 3A, 4, 5, 7 and 9, wherein the back plate electrodes form equivalent patterns on the back plate to the patterns formed by the membrane electrodes on the membranes as shown in FIGS. 3A, 4, 5, 7 and 9.

The back plate is rigid, and thus will not suffer from the effects of mass or elasticity non-uniformities, and the single-electrode membrane will be more uniform in mass distribution and elasticity. However, inter-electrode electrostatic forces will still be present which may be different and variable between facing electrodes of the membrane and back plate across the transducer. Thus providing the back plate electrodes distributed in these (or other) interspersed patterns across the back plate will result in a more uniform electrostatic force across the membrane and reduce variations in resulting displacement across the membrane between regions facing different back plate electrodes.

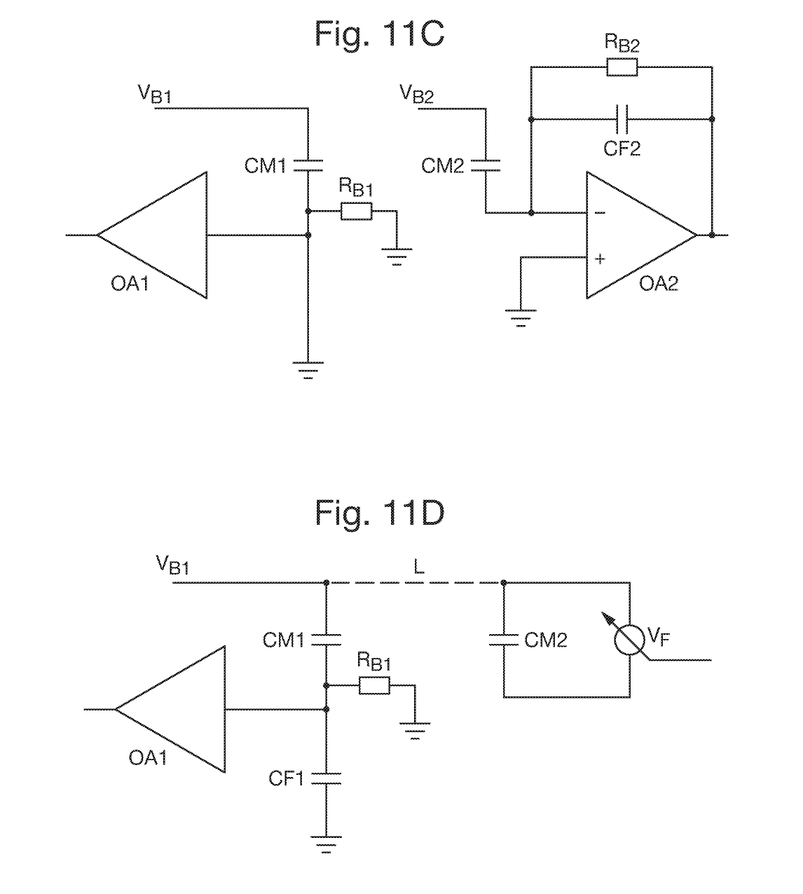

Examples of the MEMS transducer may be used in any suitable circuit configuration, depending on the intended function of the MEMS transducer. An example of an intended function of the MEMS transducer is in a capacitive microphone having separate high gain and low gain monitoring channels. Examples of circuits suitable for implementation of this intended function are shown in FIGS. 11A, 11B, 11C and 11D.

In the circuit examples shown in FIGS. 11A and 11B, the first membrane electrode 3 and second membrane electrode 5 form separate capacitors, indicated in FIGS. 11A and 11B as C_{M1} and C_{M2} respectively, with back plate electrodes. These capacitors (C_{M1} and C_{M2}) are used to detect the movement of the membrane in response to incident pressure wave (such as sound waves). The first membrane electrode 3 and second membrane electrode 5 may form capacitors with the same back plate electrode, or with separate first and second back plate electrodes respectively.

The sensing capacitors as C_{M1} and C_{M2} are connected to amplifiers OA₁ and OA₂, which are used to monitor the variation in the system. The sensing capacitors C_{M1} and C_{M2} are also connected to ground via further fixed capacitors C_{F1} and C_{F2}; The overall gain to the output of amplifier OA1 will depend on the voltage gain of amplifier OA1 but also will be dependent on the attenuation of the sensing signal (for example, microphonic signal) developed on the sensing capacitor C_{M1} by a potential divider effect of any input capacitance presented to the sensing capacitor C_{M1} at the sensing node. This input capacitance may comprise fixed capacitance C_{F1} to ground (and any other capacitance on that node, for instance the input capacitance of amplifier OA1). Similarly the overall gain to the output of amplifier OA2 will depend on the voltage gain of amplifier OA2 but also will be dependent on the attenuation of the microphonic signal developed on the sensing capacitor C_{M2} by a potential divider effect of any input capacitance presented to the sensing capacitor C_{M2} at the respective sensing node. The potential division ratios by which the microphonic signal is attenuated will be dependent on the ratio of each fixed capacitance (and any other capacitance on that node) to the respective sensing capacitance.

Accordingly, the capacitance values of the fixed capacitors C_{F1} and C_{F2} (which are usually different but may be the same) can be used to set the gain of the different monitoring systems by each presenting at the respective sensing node a different input capacitance relative to the respective sensing capacitor so as to provide a different attenuation of the sensing signal on the respective sensing capacitor. In some example the values of these fixed capacitors maybe programmable, for instance, for gain calibration purposes. A fixed capacitor may comprise a bank of capacitors which are switched in or out of circuit to alter total value, under the control of digital calibration circuitry.

The sensing capacitors C_{M1} and C_{M2} are connected via high value resistive elements R_{B1} and R_{B2}, for example back-to-back polysilicon diodes, to a reference voltage, for example ground. This defines the quiescent voltage or DC voltage on the amplifier inputs and one terminal of each sensing capacitor C_{M1} and C_{M2}.

In FIG. 11A, the sensing capacitors C_{M1} and C_{M2} receive the same bias voltage VB, at their respective other terminal to define the quiescent voltage and hence quiescent charge and hence acousto-electric sensitivity of each sensing capacitor. The amplifiers OA₁ and OA₂ are used to detect the variation in the voltage across the sensing capacitors (which, in this configuration is indicative of the variation in the membrane position). By contrast, in FIG. 11B, sensing capacitors C_{M1} and C_{M2} receive different bias voltages V_{B1} and V_{B2}, which are used to help set the gain of the sensing capacitors C_{M1} and C_{M2}. The amplifiers OA₁ and OA₂ are used to detect the variation in the capacitance of the sensing capacitors (which, in this configuration is indicative of the variation in the membrane position).

In variations of the circuits of FIGS. 11A and 11B, the role of membrane and back plate electrodes may be interchanged, so that separate back plate electrodes form separate capacitors, indicated in FIGS. 11A and 11B as C_{M1} and C_{M2} respectively, with membrane electrodes. The first back plate electrode and second back plate electrode may form capacitors with a common membrane electrode, or with separate first and second membrane electrodes respectively.

FIG. 11C illustrates a further example of a monitoring circuit comprising high and low gain channels comprising sensing capacitors C_{M1} and C_{M2} In this example, there is no fixed capacitor connected to sensing capacitor C_{M1} (ignoring the input capacitance of amplifier OA₁ and any parasitic capacitances, which may be rendered small relative to C_{M1} by careful design). Thus the quiescent charge on CM₁ once established via bias resistor RB1 is not shared with any capacitance in operation and may be regarded constant at typical operational frequencies. Since the charge on that electrode is constant, the electric field at the surface of that electrode will be constant, and so the electrostatic force on the electrode will remain constant regardless of any deflection of the membrane.

The second sensing capacitor C_{M2} is connected to a conventional operational amplifier (op-amp) based charge amplifier. In operation, the voltage on the amplifier connection of sensing capacitor C_{M2}, will be maintained constant at the same voltage as applied to the other input terminal of op amp OA₂. The electric field between the two electrodes of C_{M2} will thus be inversely proportional to the varying inter-electrode spacing, as will be the charge on each electrode. Thus the electrostatic force is inversely proportional to the inter-electrode spacing, which will vary with the incoming acoustic pressure signal.

As a result of the circuit configuration described above, the electrostatic forces between regions occupied by the respective electrodes will vary differently when acoustic signals arrive. If the electrode structures were separate, for example as shown in FIG. 2, then the motion of the region at one end of the membrane would be different from that at the other, though there would still be some mechanical coupling or mechanical cross-talk between the two, that would be non-uniform across each region and likely to introduce non-linearities in the responses, as well as possibly stimulating non-uniform motions of the membrane and possibly exciting undesirable vibrational modes. By contrast, if interspersed structures (for example, the structures illustrated in any of FIGS. 3A, 4, 5, 7 and 9) were employed, the different forces, which still giving some mechanical crosstalk in the electrical response, would give a more uniform and predictable effect across the structure.

In the example of FIG. 11C, the capacitance presented to the first sensing capacitor at the amplifier input node is ideally zero, while ideally the input capacitance of the charge amplifier is ideally infinite. For the configurations of FIGS. 11A and 11B, the capacitance presented will be between these two extremes, and still different unless the two ratios of fixed capacitance to sensing capacitances are the same. Where the sensing nodes present a different capacitance relative to the respective sensing capacitors, this results in a different attenuation of the sensing signal (for example, the microphonic signal) on the respective sensing capacitors.

FIG. 11D illustrates a further example of a monitoring amplifier configuration. A stimulus (such as an acoustic input) is monitored by amplifier OA₁ using sensing capacitor CM₁ (as discussed above in the context of FIGS. 11A to 11C). In this example, a separate capacitor CM₂ is not used for monitoring a stimulus; instead capacitor CM₂ is driven by a voltage source V_{F}. MEMS capacitor CM₂ is accordingly used to impose a mechanical electrostatic force on the common flexible membrane, dependent on voltage V_{F}.

The circuit shown in FIG. 11D may be configured such that the non-signal electrode forming one terminal of first capacitor CM₁ is isolated from the electrodes of capacitor CM₂. Alternatively, the non-signal electrode of CM₁ may be connected to the corresponding electrode of the second capacitor CM₂, as indicated by dashed connection L in FIG. 11D.

In circuits constructed in accordance with this example, voltage V_{F} may be controlled to a desired voltage to adjust the quiescent mechanical position of the membrane to adjust acoustic-electric sensitivity. In a further application of this example, voltage V_{F} may be controlled to reduce the excursion of the membrane in a force-feedback mode (similar to that disclosed in U.S. Ser. No. 15/363,863, as discussed above) using feedback circuitry driven by the output of amplifier OA₁ (not illustrated), the acoustic signal being monitored by the variation in V_{F}.

If the electrode structure of FIG. 2 were used in conjunction with the circuit example shown diagrammatically in FIG. 11D, then one end of the rectangular membrane would be subject to the forces controlled by voltage VF, whereas the other end of the membrane would be largely unaffected. Using the configurations of FIGS. 3A, 4, 5, 7 and 9 the membrane position would be substantially more uniform and effective in controlling the sensitivity or nulling the excursion.

As will be appreciated, the above detailed description is provided by way of example only, and the scope of the invention is defined by the claims.

It should be understood that the various relative terms upper, lower, top, bottom, underside, overlying, beneath, etc. that are used in the present description should not be in any way construed as limiting to any particular orientation of the MEMS transducer during any fabrication step and/or it orientation in any package, or indeed the orientation of the package in any apparatus. Thus the relative terms shall be construed accordingly.

Examples described herein may be usefully implemented in a range of different material systems, however the examples described herein are particularly advantageous for MEMS transducers having membrane layers comprising silicon nitride.

In the examples described above it is noted that references to a MEMS transducer may comprise various forms of transducer element. For example, a MEMS transducer may be typically mounted on a die and may comprise a single membrane and back-plate combination. In another example a MEMS transducer die comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprise different individual transducers positioned to receive acoustic signals from different acoustic channels.

According to one or more examples, the transducer may further comprise an integrated circuit die, the integrated circuit die comprising analogue circuitry or digital circuitry. The integrated circuit die comprises a programmable digital signal processor.

A monitoring circuit may be provided according to one or more example embodiments for use in a capacitive microphone system, comprising a MEMS transducer, wherein the monitoring circuit is configured to use separate high gain and low gain monitoring channels, both of which are configured to utilise a single flexible membrane of the MEMS transducer as the sensing member, wherein the high gain and low gain monitoring channels are further configured to each use a different sensing capacitor, and wherein one of a first membrane electrode of the flexible membrane and a second membrane electrode of the flexible membrane is an electrode in each of the sensing capacitors.

According to a further aspect there is provided a monitoring circuit for use in a capacitive microphone system, comprising a MEMS transducer, the MEMS transducer comprising a flexible membrane and a back plate, the back plate comprising one or more back plate electrodes and the flexible membrane comprising one or more membrane electrodes, wherein at least one of the back plate and the flexible membrane comprises a plurality of electrodes, wherein;
the monitoring circuit is configured to use separate high gain and low gain monitoring channels, the high gain and low gain monitoring channels being configured to utilise a single flexible membrane of the MEMS transducer as the sensing member; and
the high gain and low gain monitoring channels are each configured to use a different sensing capacitor, the sensing capacitors configured to be used by the high gain and low gain monitoring channels each comprising a different combination of the one or more back plate electrodes and the one or more membrane electrodes.

According to an example of this aspect:

a respective output of each sensing capacitor is connected to a respective amplifier input at a sensing node;
each sensing node presents a different input capacitance relative to the respective sensing capacitor so as to present a different gain.

According to a further example of this aspect:

a respective output of each sensing capacitor is connected to a respective amplifier input at a sensing node;
each sensing node presents a different input capacitance relative to the respective sensing capacitor so as to provide a different attenuation of the microphonic signal on the respective sensing capacitor.

According to a further aspect there is provided a monitoring circuit for use in a capacitive microphone system, comprising a MEMS transducer, the MEMS transducer comprising a flexible membrane and a back plate, the back plate comprising one or more back plate electrodes and the flexible membrane comprising one or more membrane electrodes, wherein at least one of the back plate and the flexible membrane comprises a plurality of electrodes, wherein;
the monitoring circuit is configured to use a monitor channel and a force channel, wherein the monitoring channel and the force channel are each configured to use a respective capacitor, the capacitors configured to be used by the monitoring channel and the force channel each comprising a different combination of the one or more back plate electrodes and the one or more membrane electrodes.

A MEMS transducer according to a further aspect may comprise a monitoring circuit according to any of the examples or aspects described herein.

An electronic device according to a further aspect may comprise a MEMS transducer according to any of the examples described herein and/or a monitoring circuit according to any of the examples or aspects described herein. The device may be at least one of: a portable device; a battery power device; a computing device; a communications device; a gaming device; a mobile telephone; an earphone or in-ear hearing aid, a personal media player; a laptop, tablet or notebook computing device.

Also provided are methods of fabricating a MEMS transducer according to any of the examples or aspects described herein.

It is noted that the examples described above may be used in a range of devices, including, but not limited to: analogue microphones, digital microphones, speakers, pressure sensors or ultrasonic transducers. The device may be at least one of: a portable device; a battery power device; a computing device; a communications device; a gaming device; a mobile telephone; an earphone or in-ear hearing aid, a personal media player; a laptop, tablet or notebook computing device.

The invention may also be used in a number of applications, including, but not limited to, consumer applications, medical applications, industrial applications and automotive applications. For example, typical consumer applications include portable audio players, wearable devices, laptops, mobile phones, PDAs and personal computers. Examples may also be used in voice activated or voice controlled devices. Typical medical applications include hearing aids. Typical industrial applications include active noise cancellation. Typical automotive applications include hands-free sets, acoustic crash sensors and active noise cancellation.

It should be noted that the above-mentioned examples illustrate rather than limit the invention, and that those skilled in the art will be able to design many alternative configurations without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A MEMS transducer comprising:
a flexible membrane, the flexible membrane comprising a first membrane electrode;
a back plate, the back plate comprising a first back plate electrode;
wherein the back plate is supported in a spaced relation with respect to the flexible membrane; and
wherein the MEMS transducer is configured to provide electrical connections to the first membrane electrode and the first back plate electrode;
the flexible membrane further comprising a second membrane electrode, the second membrane electrode being electrically isolated from the first membrane electrode,
wherein the first membrane electrode and the second membrane electrode are arranged to reduce variation in electrostatic forces across the flexible membrane.

2. The MEMS transducer of claim 1, wherein each of the first membrane electrode and the second membrane electrode are divided into a plurality of discrete regions.

3. The MEMS transducer of claim 2 wherein the plurality of discrete regions of the first membrane electrode and the plurality of discrete regions of the second membrane electrode are interspersed across the flexible membrane.

4. The MEMS transducer of claim 1, wherein the first membrane electrode and second membrane electrode are arranged to provide a flexible membrane electrode layout having an order of rotational symmetry.

5. The MEMS transducer of claim 4, wherein the first membrane electrode and second membrane electrode are arranged to provide a flexible membrane layout having two or more orders of rotational symmetry.

6. The MEMS transducer of claim 1, wherein the outline shape formed by the first membrane electrode and second membrane electrode is substantially circular, or wherein the outline shape is substantially rectangular.

7. The MEMS transducer of claim 1, wherein the first membrane electrode and second membrane electrode are each divided into plural annular regions, the plurality of annular regions being arranged coaxially in a plane, the plurality of annular regions having different inner and outer radii from one another and being arranged such that the first membrane electrode and second membrane electrode alternate with radial separation from a centre of the annular regions.

8. The MEMS transducer of claim 1, wherein the first membrane electrode and second membrane electrode are each divided into plural sectors of equal area, the plurality of sectors being arranged such that sectors of the first membrane electrode and sectors of the second membrane electrode alternate around the membrane.

9. The MEMS transducer of claim 8, wherein the first membrane electrode and second membrane electrode are each divided into 4 sectors.

10. The MEMS transducer of claim 1:
wherein the first membrane electrode and second membrane electrode are each divided into plural annular portions, the annular portions in turn being divided into plural sectors;
wherein the first membrane electrode and second membrane electrode are arranged such that portions of the first membrane electrode and second membrane electrode alternate with increasing radial separation from the centre of the annuli and also around the membrane, and also alternate within each annular portion between sectors, such that the first membrane electrode and second membrane electrode both delineate a substantially spiral path.

11. The MEMS transducer of claim 1, wherein the first membrane electrode and second membrane electrode each comprise a plurality of substantially rectangular discrete regions, the substantially rectangular regions being interleaved so as to alternate along a length of the flexible membrane.

12. The MEMS transducer of claim 1, wherein the outline shape formed by the first membrane electrode and second membrane electrode is substantially the same as the shape formed by the flexible membrane.

13. The MEMS transducer of claim 1:
wherein the back plate is configured such that a surface of the back plate comprising the first back plate electrode and facing the flexible membrane is substantially parallel to a surface of flexible membrane comprising the first membrane electrode and facing the back plate; and
wherein the shape of the first back plate electrode at least partially mirrors the shape of the first membrane electrode.

14. The MEMS transducer of claim 13:
wherein the surface of the back plate comprising the first back plate electrode further comprises a second back plate electrode;
wherein the surface of the flexible membrane comprising the first membrane electrode further comprises the second membrane electrode; and
wherein the shape of the second back plate electrode at least partially mirrors the shape of the second membrane electrode.

15. A gain monitoring circuit for use in a capacitive microphone system, comprising a MEMS transducer, wherein the monitoring circuit is configured to use separate high gain and low gain monitoring channels, both of which are configured to utilise a single flexible membrane of the MEMS transducer as the sensing member, wherein the high gain and low gain monitoring channels are further configured to each use a different sensing capacitor, and wherein one of a first membrane electrode of the flexible membrane and a second membrane electrode of the flexible membrane is an electrode in each of the sensing capacitors.

16. The gain monitoring circuit of claim 15, wherein the sensing capacitors of the high gain and low gain monitoring channels are connected to a single bias voltage, and amplifiers connected to the sensing capacitors are configured to monitor the movement of the flexible membrane by detecting variations in the voltage across the sensing capacitors.

17. The gain monitoring circuit of claim 15, wherein the sensing capacitors of the high gain and low gain monitoring channels are connected to different bias voltages, and amplifiers connected to the sensing capacitors are configured to monitor the movement of the flexible membrane by detecting variations in the capacitance of the sensing capacitors.

18. A MEMS transducer comprising:
a flexible membrane, the flexible membrane comprising a first membrane electrode;
a back plate, the back plate comprising a first back plate electrode;
wherein the back plate is supported in a spaced relation with respect to the flexible membrane; and
wherein the MEMS transducer is configured to provide electrical connections to the first membrane electrode and the first back plate electrode;
the flexible membrane further comprising a second membrane electrode, the second membrane electrode being electrically isolated from the first membrane electrode,
wherein the first membrane electrode and the second membrane electrode are arranged to suppress resonant modes of the flexible membrane.

19. A MEMS transducer comprising:
a flexible membrane, the flexible membrane comprising a first membrane electrode;
a back plate, the back plate comprising a first back plate electrode;
wherein the back plate is supported in a spaced relation with respect to the flexible membrane; and
wherein the MEMS transducer is configured to provide electrical connections to the first membrane electrode and the first back plate electrode;
the back plate further comprising a second back plate electrode, the second back plate electrode being electrically isolated from the first back plate electrode,
wherein the first back plate electrode and the second back plate electrode are arranged to reduce variation in electrostatic forces across the flexible membrane.

20. A monitoring circuit for use in a capacitive microphone system comprising a MEMS transducer, the MEMS transducer comprising a flexible membrane and a back plate, the back plate comprising first and second back plate electrodes, wherein;
the monitoring circuit is configured to use separate high gain and low gain monitoring channels, the high gain and low gain monitoring channels being configured to utilise a single flexible membrane of the MEMS transducer as the sensing member; and
the high gain and low gain monitoring channels are each configured to use a different sensing capacitor, wherein one of the first back plate electrode and the second back plate electrode of the flexible membrane is an electrode in each of the sensing capacitors.
